(19) United States
(12) Patent Application Publication
(10) Pub. No.: US 2015/0215501 A1
(43) Pub. Date: Jul. 30, 2015

(54) CAMERA MODULE

(71) Applicant: SAMSUNG ELECTRO-MECHANICS CO., LTD., Suwon-Si (KR)

(72) Inventor: Ho-Yun CHO, Suwon-Si (KR)

(73) Assignee: SAMSUNG ELECTRO-MECHANICS CO., LTD.

(21) Appl. No.: 14/495,531

(22) Filed: Sep. 24, 2014

(30) Foreign Application Priority Data
Jan. 29, 2014 (KR) 10-2014-0011665

(51) Int. Cl. H04N 5/225; H05K 9/00

(52) U.S. Cl. CPC H04N 5/2252; H05K 9/0058; H05K 9/006; H04N 5/2253

(57) ABSTRACT

A camera module is disclosed. The camera module in accordance with an embodiment of the present invention includes: an optical unit; an image sensor arranged in a lower side of the optical unit and configure to receive light having penetrated the optical unit; and a shielding member formed on a surface of the image sensor so as to shield electromagnetic waves brought into the image sensor.

### CROSS-REFERENCE TO RELATED APPLICATIONS

This application claims the benefit of Korean Patent Application No. 10-2014-0011665, filed with the Korean Intellectual Property Office on Jan. 29, 2014, the disclosure of which is incorporated herein by reference in its entirety.

### BACKGROUND

1. Technical Field

The present invention relates to a camera module.

2. Background Art

As the camera functionality has become an essential part of today's mobile phones, there has been an increasing demand for ultra-small and high-quality camera modules. Such camera modules can include a CMOS image sensor or a CCD image sensor.

There can be several causes for lowering the performance of a camera module, one of which being false operation and image defect due to electromagnetic waves from outside.

Specifically, in case outside electromagnetic waves are not filtered but brought into the camera module, an image sensor chip is disturbed and malfunctions, resulting in what is commonly referred to as electro-magnetic interference (EMI).

The related art of the present invention is disclosed in Korea Patent Publication No. 10-2009-0117238 (WAFER LEVEL CAMERA MODULE AND METHOD OF MANUFACTURING THE SAME; laid open on Nov. 12, 2009).

### SUMMARY

The present invention provides a camera module having an EMI shielding member formed on an image sensor.

An aspect of the present invention provides a camera module, which includes:

an optical unit: an image sensor arranged in a lower side of the optical unit and configure to receive light having penetrated the optical unit; and a shielding member formed on a surface of the image sensor so as to shield electromagnetic waves brought into the image sensor.

The shielding member can be formed to be transparent so that the light having penetrated the optical unit is incident at the image sensor.

The shielding member can cover an entire upper face of the image sensor.

The shielding member can be formed to have a mesh structure.

The shielding member can be made of a conductive material.

The camera module can further include housing arranged above the image sensor so as to receive the optical unit therein.

The camera module can further include a printed circuit board having the image sensor mounted thereon and coupled at a lower side of the housing.

The camera module can further include a shield can coupled at an outside of the housing so as to cover the housing.

The shield can can have an opening formed at an upper portion thereof corresponding to a position of the optical unit.

### BRIEF DESCRIPTION OF THE DRAWINGS

FIG. 1 shows a camera module in accordance with an embodiment of the present invention.

FIG. 2 and FIG. 3 show image sensors of the camera module in accordance with various embodiments of the present invention.

### DETAILED DESCRIPTION

Hereinafter, certain embodiments of a camera module in accordance with the present invention will be described in detail with reference to the accompanying drawings. In describing the present invention with reference to the accompanying drawings, any identical or corresponding elements will be assigned with same reference numerals, and no redundant description thereof will be provided.

Terms such as “first” and “second” can be used in merely distinguishing one element from other identical or corresponding elements, but the above elements shall not be restricted to the above terms.

When one element is described to be “coupled” to another element, it does not refer to a physical, direct contact between these elements only, but it shall also include the possibility of yet another element being interposed between these elements and each of these elements being in contact with said yet another element.

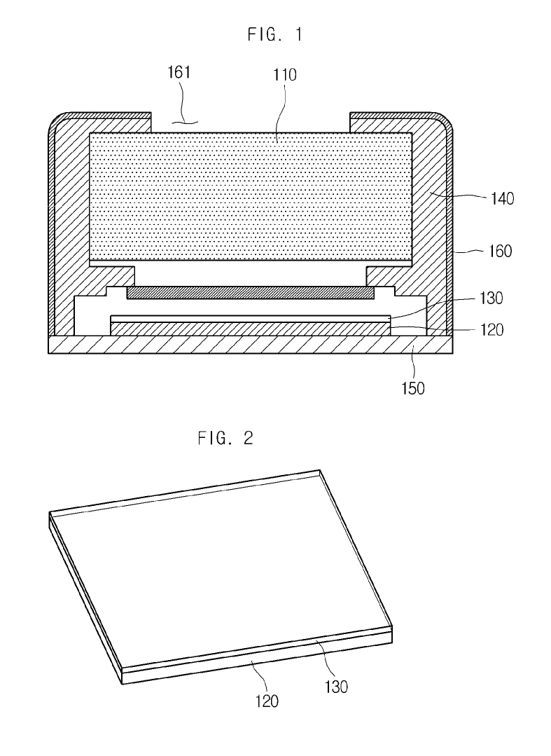

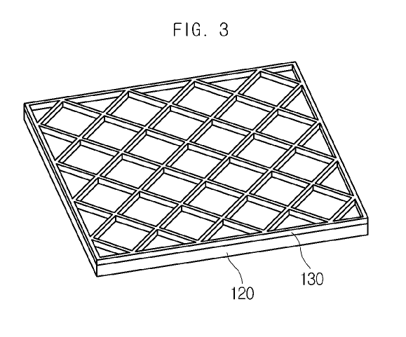

FIG. 1 shows a camera module in accordance with an embodiment of the present invention, and FIG. 2 and FIG. 3 show image sensors of the camera module in accordance with various embodiments of the present invention.

Referring to FIG. 1, a camera module 100 in accordance with an embodiment of the present invention can include an optical unit 110, an image sensor 120 and a shielding member 130, and can further include housing 140, a printed circuit board 150 and a shield can 160.

The optical unit 110 is a portion that receives light. The optical unit 110 can include a bobbin, a lens unit and a driving unit.

The lens unit can include a lens and a lens barrel. The lens unit can be installed within the bobbin. The driving unit can drive the lens unit in an optical-axis direction. Accordingly, an autofocusing function of the camera module 100 can be implemented.

The driving unit can drive the lens unit by use of a VCM (voice coil motor) method, which drives the lens unit up and down using electromagnetic force, an ultrasonic motor method, which uses a piezoelectric device, etc.

The image sensor 120 is a part that is arranged in a lower side of the optical unit 110 and receives light that has penetrated the optical unit 110. The image sensor 120 is arranged to be separated from the optical unit 110.

The shielding member 130 is formed on a surface of the image sensor 120 in order to shield electromagnetic waves brought into the image sensor 120. The shielding member 130 can be formed on an upper face of the image sensor 120.

As illustrated in FIG. 2, the shielding member 130 can be formed to be transparent. By forming the shielding member 130 to be transparent, the light having penetrated the optical unit 110 can be incident at the image sensor 120 without interruption.

The shielding member 130 can be formed to cover the entire upper face of the image sensor 120. By forming the shielding member 130 to cover the entire upper face of the image sensor 120, the effect of shielding electromagnetic waves can be enhanced.

The shielding member 130 can be made of a conductive material. For example, the shielding member 130 can be made of a metal. By using the shielding member 130 made of a conductive material, the effect of shielding electromagnetic waves can be enhanced.

The shielding member 130 can be made of a transparent conductive material. For example, the shielding member 130 can be made of ITO (indium tin oxide), grapheme, etc.

The shielding member 130 can be formed by a deposition method, for example, sputtering. The shielding member 130 can be also formed by printing or coating a shielding material.

The shielding member 130 can be formed to have a mesh structure. By forming the shielding member 130 to have a mesh structure, the light having penetrated the optical unit 110 can be incident at the image sensor 120 without interruption even if the shielding member 130 is made of an opaque material.

The housing 140 is a case that has the optical unit 110 received therein. The housing 140 can have a top face and a bottom face that are open. The optical unit 110 can be received through the open top face. The image sensor 120 can be received in the bottom face.

The printed circuit board 150 is a board that has the image sensor 120 mounted thereon and can be coupled at a lower side of the housing 140. The printed circuit board 150 can supply electric power to the image sensor 120 and the driving unit of the optical unit 110.

The shield can 160 is coupled to an outside of the housing 140 so as to cover the housing 140 and shields electromagnetic waves brought in from outside. The shield can 160 can be made of a metallic material. Moreover, the shield can 160 can be attached over the printed circuit board 150.

The shield can 160 can have an opening 161 formed at an upper portion thereof corresponding to a position of the optical unit 110. The light can be incident at the optical unit 110 through the opening 161. Such an opening 161 can be formed to be extended up to the housing 140, as shown in FIG. 1.

As described above, with the camera module in accordance with an embodiment of the present invention, the electromagnetic waves brought into the image sensor can be effectively shielded, and electromagnetic waves generated within the camera module can be also shielded effectively.

Although certain embodiments of the present invention have been described hitherto, it shall be appreciated that the present invention can be variously modified and permutated by those of ordinary skill in the art to which the present invention pertains by supplementing, modifying, deleting and/or adding certain element(s) without departing from the technical ideas of the present invention, which shall be defined by the claims appended below. It shall be also appreciated that such modification and/or permutation are also included in the claimed scope of the present invention.

What is claimed is:

1. A camera module, comprising:
an optical unit;
an image sensor arranged in a lower side of the optical unit and configure to receive light having penetrated the optical unit; and
a shielding member formed on a surface of the image sensor so as to shield electromagnetic waves brought into the image sensor.

2. The camera module of claim 1, wherein the shielding member is formed to be transparent so that the light having penetrated the optical unit is incident at the image sensor.

3. The camera module of claim 2, wherein the shielding member covers an entire upper face of the image sensor.

4. The camera module of claim 1, wherein the shielding member is formed to have a mesh structure.

5. The camera module of claim 1, wherein the shielding member is made of a conductive material.

6. The camera module of claim 1, further comprising housing arranged above the image sensor so as to receive the optical unit therein.

7. The camera module of claim 6, further comprising a printed circuit board having the image sensor mounted thereon and coupled at a lower side of the housing.

8. The camera module of claim 6, further comprising a shield can coupled at an outside of the housing so as to cover the housing.

9. The camera module of claim 8, wherein the shield can has an opening formed at an upper portion thereof corresponding to a position of the optical unit.
